(19) United States
(12) Patent Application Publication
(10) Pub. No.: US 2017/0162825 A1
(43) Pub. Date: Jun. 8, 2017

(54) COMPOSITE SUBSTRATE, FLEXIBLE DISPLAY DEVICE AND FABRICATION METHOD THEREOF

(71) Applicants: Shanghai Tianma Micro-electronics Co., Ltd., Shanghai (CN); Tianma Micro-electronics Co., Ltd., Shenzhen (CN)

(72) Inventors: CANJUN XIAO, Shanghai (CN); ZHENGZHONG CHEN, Shanghai (CN)

(73) Assignees: Shanghai Tianma Micro-electronics Co., Ltd.; Tianma Micro-electronics Co., Ltd.

(21) Appl. No.: 15/158,740

(22) Filed: May 19, 2016

(30) Foreign Application Priority Data
Dec. 8, 2015 (CN) 2015-10898106.2

(51) Int. Cl. H01L 51/52; H01L 51/00; H01L 27/32; H01L 51/56

(52) U.S. Cl. CPC H01L 51/5253; H01L 51/56; H01L 51/003; H01L 27/3244; H01L 51/0034; H01L 2251/558; H01L 2251/5338; H01L 2251/301; H01L 2251/303

(57) ABSTRACT

A composite substrate for a flexible display device, a flexible display device and a flexible display device fabrication method are provided. The flexible display device comprises a composite substrate including a first organic film, a second organic film and at least one inorganic film sandwiched between the first organic film and the second organic film, and a display component disposed on the composite substrate. The display component is disposed on the second organic film, and the composite substrate is configured to support the display component and encapsulate the display component.

### CROSS-REFERENCES TO RELATED APPLICATIONS

This application claims priority of Chinese Patent Application No. 201510898106.2, filed on Dec. 8, 2015, the entire contents of which are hereby incorporated by reference.

### FIELD OF THE INVENTION

The present disclosure generally relates to the field of display panel technology and, more particularly, relates to a composite substrate, a flexible display device and fabrication techniques thereof.

### BACKGROUND

Display panels, such as thin film transistor-liquid crystal displays (TFT-LCDs), organic light-emitting diode (OLED) display panels, low-temperature polysilicon (LTPS) display panels, and plasma display panels (PDP), have been widely used in a large variety of portable electronic devices including cell phones, and personal digital assistants (PDAs), etc. Driven by the competitive market, display devices having a lighter weight, better image performance and lower price are highly desired.

Existing fabrication process of flexible organic electroluminescent display devices often comprises: (1) forming a release layer on a glass substrate; (2) forming a flexible substrate (e.g., a polyimide (PI) layer) on the release layer; (3) fabricating a thin-film transistor (TFT) driving circuit on the flexible substrate; (4) depositing organic light-emitting elements; (5) forming an encapsulation layer on the organic light-emitting elements; (6) attaching an upper protective film; (7) detaching the flexible substrate from the glass substrate; and (8) attaching a lower protective film to the flexible substrate.

However, because the flexible substrate (e.g., PI layer) detached from the glass substrate is substantially soft, certain issues may rise when attaching the lower protective film to the flexible substrate. For example, bubbles may occur, and the TFTs and organic light-emitting elements may be damaged, etc., reducing the production yield of the flexible display devices. If the release layer or the glass substrate has a non-uniform thickness, the PI layer coated on the release layer may also have a non-uniform thickness, degrading the image performance of the display device.

In addition, the release layer often requires high temperature resistant materials, and the material choices are substantially limited. On the other hand, the release layer has a substantially weak adhesive, thus the flexible substrate may be displaced during the fabrication process, degrading the production yield and the image performance of the display device. A certain portion of the release layer may be remained on the display device, increasing the thickness of the display device and dissatisfying the market demand for thin display devices.

The disclosed composite substrate, flexible display device and fabrication techniques thereof are directed to solve one or more problems set forth above and other problems.

### BRIEF SUMMARY OF THE DISCLOSURE

One aspect of the present disclosure provides a composite substrate for a flexible display device. The composite substrate comprises a first organic film, a second organic film, and at least one inorganic film sandwiched between the first organic film and the second organic film. The composite substrate is configured to support a display component disposed on the composite substrate and encapsulate the display component.

Another aspect of the present disclosure provides a flexible display device. The flexible display device comprises a composite substrate including a first organic film, a second organic film and at least one inorganic film sandwiched between the first organic film and the second organic film, and a display component disposed on the composite substrate. The display component is disposed on the second organic film, and the composite substrate is configured to support the display component and encapsulate the display component.

Another aspect of the present disclosure provides a flexible display device fabrication method. The method comprises providing a first substrate, forming a composite substrate on the first substrate, forming a display component on the composite substrate, and detaching the composite substrate from the first substrate. Forming a composite substrate further includes forming a first organic film on the first substrate, forming at least one inorganic film on the first organic film, and forming a second organic film on the first substrate having the inorganic film. The display component is formed on the second organic film, and the composite substrate is configured to support the display component and encapsulate the display component.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a cross-sectional view of an exemplary flexible display device during certain stages of the fabrication process in FIG. 4 consistent with disclosed embodiments;

FIG. 2 illustrates a cross-sectional view of an exemplary composite substrate consistent with disclosed embodiments;

FIG. 3 illustrates a cross-sectional view of an exemplary flexible display device consistent with disclosed embodiments;

FIG. 4 illustrates a flow chart of an exemplary flexible display device fabrication process consistent with disclosed embodiments; and

FIG. 5 illustrates a cross-sectional view of another exemplary composite substrate consistent with disclosed embodiments.

### DETAILED DESCRIPTION

Reference will now be made in detail to exemplary embodiments of the invention, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are some but not all of the embodiments of the present invention. Based on the disclosed embodiments, persons of ordinary skill in the art may derive other embodiments consistent with the present disclosure, all of which are within the scope of the present invention.

The present disclosure provides an improved composite substrate, which may be implemented as a flexible substrate in a flexible display device. The disclosed composite substrate may not only support the display component (e.g., OLEDs and TFTs) disposed on the composite substrate, but also efficiently prevent moisture and oxygen from penetrating the display component. The production yield of the flexible display devices may be improved, and the image performance of the flexible display devices may be enhanced accordingly.

FIG. 5 illustrates a cross-sectional view of an exemplary composite substrate consistent with disclosed embodiments. As shown in FIG. 5, the composite substrate 2 may include a first organic film 21, a second organic film 22, and at least one inorganic film 23 sandwiched between the first organic film 21 and the second organic film 22. In one embodiment, as shown in FIG. 5, one inorganic film 23 may be disposed between the first organic film 21 and the second organic film 22.

Inorganic films often have desired moisture and oxygen barrier properties, but are substantially rigid. Organic films have poorer moisture and oxygen barrier properties than inorganic films, but are able to eliminate the stress generated by inorganic film. Thus, the inorganic film 23 may function as a barrier layer with desired moisture and oxygen barrier properties. The first organic film 21, the second organic film 22, and at least one inorganic film 23 may provide desired moisture and oxygen barrier properties in the composite substrate 2 and, meanwhile, minimize the stress of the composite substrate 2.

When the composite substrate 2 is implemented as the flexible substrate in the flexible display device, a display component (e.g., OLEDs and TFTs) may be disposed on the composite substrate 2. The display component often requires a protection from moisture and oxygen penetration in electronic device, otherwise the performance, stability and durability of the display component may be affected. The composite substrate 2 may not only support the display component, but also efficiently prevent moisture and oxygen from penetrating the display component. That is, the composite substrate 2 may function as a substrate or a supporter for the display component to be disposed on and, meanwhile, an encapsulation layer to efficiently encapsulate the display component

The numbers of layers of the inorganic films 23 in the composite substrate 2 may be determined by predetermined algorithms. The thickness of the first organic film 21, the second organic film 22, and the inorganic film 23 may also be determined by predetermined algorithms. The predetermined algorithms may be designed according to various requirements of the composite substrate 2, such as the moisture and oxygen barrier properties, flexibility, and light transmittance, etc.

In one embodiment, the thickness of the first organic film 21 and the second organic film 22 may be approximately 10 μm-20 μm, respectively, and the thickness of the inorganic film 23 may be approximately 50 nm-500 nm. The overall thickness of the composite substrate 2 may be approximately less than or equal to 50 μm. The material of the first organic film 21 and the second organic film 22 may be polyimide (PI). Because the PI often has a desired heat resistance, when the TFTs are fabricated on the composite substrate 2 in the subsequent process, the composite substrate 2 may be able to stand the high temperature required for fabricating the TFTs. The materials of the inorganic film 23 may include at least one of silicon oxide, silicon nitride, aluminum, titanium, molybdenum, and aluminum oxide, such that the composite substrate 2 may exhibit a desired heat transfer capability.

Especially when the overall thickness of the composite substrate 2 is approximately less than or equal to 50 μm, on one hand, the composite substrate 2 may be substantially thin, satisfying the market demand for thin display devices. On the other hand, the composite substrate 2 may exhibit a desired heat resistance, an efficient heat transfer capability, and desired moisture and oxygen barrier properties, preventing the display component from the heat generated in the subsequent fabrication process (e.g., TFT fabrication, laser cutting), as well as the moisture and oxygen barrier in the environment.

Because the composite substrate 2 itself may efficiently prevent moisture and oxygen from penetrating the display component, an extra protective layer (e.g., the lower protective layer used in the conventional flexible display) may be no longer attached to a surface of the composite substrate 2 away from the display component. The technical issues of attaching the lower protective layer to the composite substrate 2, such as bubbles, damages to the TFTs and organic light-emitting elements, may be solved. When the disclosed composite substrate is implemented as the flexible substrate in the flexible display device, the production yield of the flexible display devices may be improved, and the image performance of the flexible display devices may be enhanced accordingly.

In one embodiment, the composite substrate may also include at least one third organic film, which may be disposed between the first organic film and the second organic film. FIG. 2 illustrates a cross-sectional view of another exemplary composite substrate consistent with disclosed embodiments. The similarities between FIG. 5 and FIG. 2 are not repeated here, while certain differences may be illustrated.

As shown in FIG. 2, the composite substrate 2 may include a first organic film 21, a second organic film 22, at least one third organic film 24 and at least one inorganic film 23 sandwiched between the first organic film 21 and the second organic film 22. The third organic film 24 and the inorganic film 23 may be alternately arranged. In one embodiment, as shown in FIG. 2, the composite substrate 2 may include one third organic film 24 and one inorganic film 23 sandwiched between the first organic film 21 and the second organic film 22.

Inorganic films often have desired moisture and oxygen barrier properties, but are substantially rigid. Organic films have poorer moisture and oxygen barrier properties than inorganic films, but are able to eliminate the stress generated by inorganic film. Thus, alternating arranged the third organic films 24 and the inorganic films 23 in the composite substrate 2 may provide desired moisture and oxygen barrier properties in the composite substrate 2 and, meanwhile, minimize the stress of the composite substrate 2. Accordingly, the display component (e.g., OLEDs and TFTs) disposed on the composite substrate 2 may be less affected by the moisture, oxygen, stress, etc.

In one embodiment, the inorganic film 23 may be disposed within the region of the composite substrate 2 further away from the display component than the third organic film 24. Because moisture and oxygen may be most likely to permeate the display panel from the region of the composite substrate 2 far away from the display component, and inorganic film 23 with desired moisture and oxygen barrier properties may protect the display component from moisture and oxygen more efficiently.

The numbers of layers of the third organic films 24 and the inorganic films 23 in the composite substrate 2 may be determined by predetermined algorithms. The thickness of the first organic film 21, the second organic film 22, the third organic film 24, and the inorganic film 23 may also be determined by predetermined algorithms. The predetermined algorithms may be designed according to various requirements of the composite substrate 2, such as moisture and oxygen barrier properties, flexibility, light transmittance, etc.

In one embodiment, the thickness of the first organic film 21, the second organic film 22, and the third organic film 24 may be approximately 10 μm-20 μm, respectively, and the thickness of the inorganic film 23 may be approximately 50 nm-500 nm. The overall thickness of the composite substrate 2 may be approximately less than or equal to 50 μm. The material of the first organic film 21, the second organic film 22, and the third organic film 24 may be polyimide (PI) with desired heat resistance. The materials of the inorganic film 23 may include at least one of silicon oxide, silicon nitride, aluminum, titanium, molybdenum, and aluminum oxide, such that the composite substrate 2 may exhibit a desired heat transfer capability.

Especially when the overall thickness of the composite substrate 2 is approximately less than or equal to 50 μm, on one hand, the composite substrate 2 may be substantially thin, satisfying the market demand for thin display devices. On the other hand, the composite substrate 2 may exhibit a desired heat resistance, an efficient heat transfer capability, and desired moisture and oxygen barrier properties, preventing the display component from the heat generated in the subsequent fabrication process (e.g., TFT fabrication, laser cutting), as well as the moisture and oxygen barrier in the environment.

The present disclosure also provides an improved flexible display device. FIG. 3 illustrates a cross-sectional view of an exemplary flexible display device consistent with disclosed embodiments. The flexible display device may include any one of the disclosed composite substrates. For example, the flexible display device may be a smartphone, a tablet, a wearable device, etc., which is capable of displaying images and/or videos. Further, the flexible display device may be any flexible electronic device or any electronic component capable of displaying images and/or videos and including any one of the disclosed composite substrates.

As shown in FIG. 3, the flexible display device may include a composite substrate 2, a display component including a driving element 3 and a displaying element 4, an encapsulation layer 5 and a protective layer 6. The detail structure of the composite substrate 2 may be referred to the description of FIG. 5 and FIG. 2, which are not repeated here. The display component including the driving element 3 and the displaying element 4 may be disposed on the composite substrate 2. The driving element 3 may drive the displaying element 4 to display images and/or videos.

In one embodiment, the driving element 3 may include a plurality of thin-film transistors (TFTs), and the displaying element 4 may include a plurality of organic light-emitting diodes (OLEDs). In another embodiment, the displaying element 4 may include a plurality of light-emitting diodes, quantum dots, low-temperature polysilicon, or any other displaying elements capable of displaying images and/or videos, and the driving element 3 may include TFTs or any other driving elements capable of driving the corresponding displaying element 4. For example, the display component may be active matrix organic light-emitting diodes (AMOLED), passive matrix organic light-emitting diodes (PMOLED), etc.

The encapsulation layer 5 may be disposed on the displaying element 4, which may seal the display component and prevent moisture and oxygen from penetrating the display component. The protective layer 6 may be disposed on the encapsulation layer 5, protecting the encapsulation layer 5. In one embodiment, the encapsulation layer 5 may be a thin film encapsulation (TFE).

Because the composite substrate 2 itself may be able to efficiently prevent moisture and oxygen from penetrating the display component (i.e., encapsulate the display component), an extra protective layer (e.g., the lower protective layer used in the conventional flexible display) may be no longer attached to a surface of the composite substrate 2 away from the display component. The technical issues of attaching the lower protective layer to the composite substrate 2, such as bubbles, damages to the TFTs and organic light-emitting elements, may be solved. Accordingly, the production yield of the flexible display devices may be improved, and the image performance of the flexible display devices may be enhanced.

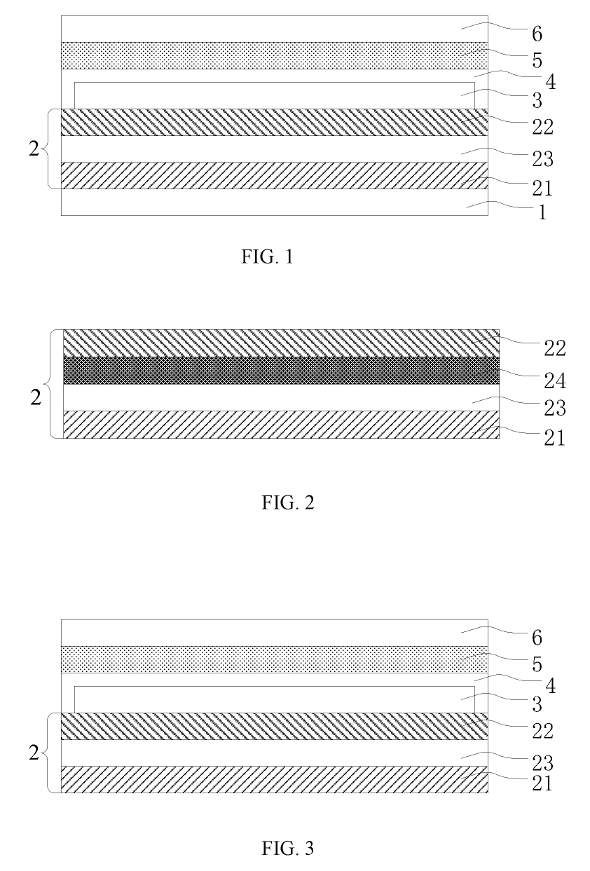

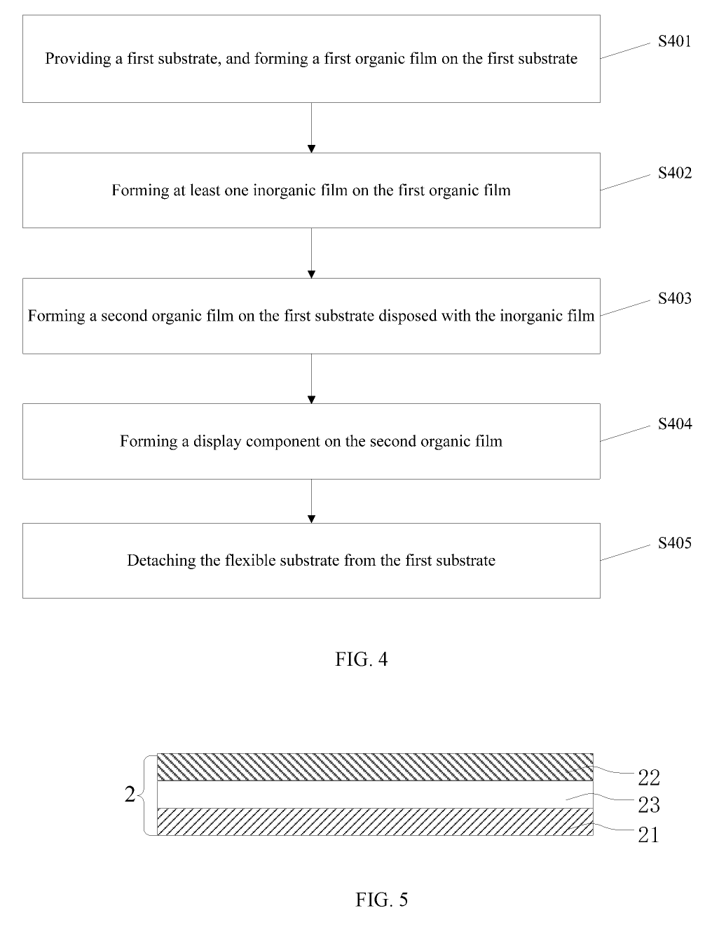

FIG. 4 illustrates a flow chart of an exemplary flexible display device fabrication process consistent with disclosed embodiments. FIG. 1 illustrates a cross-sectional view of an exemplary flexible display device during certain stages of the fabrication process in FIG. 4 consistent with disclosed embodiments. The flexible display device fabrication process may be illustrated in the accompanying FIG. 1 and FIG. 4.

As shown in FIG. 4, at the beginning, a first substrate is provided, and a first organic film is formed on the first substrate (S401). FIG. 1 illustrates a cross-sectional view of a corresponding structure. As shown in FIG. 1, the first substrate 1 may be a glass substrate or other rigid substrates, and the first organic film 21 is formed on the first substrate. In particular, a first film may be coated on the first substrate, and then baked to obtain the first organic film. The baking temperature may be higher than or equal to approximately 400° C., and the baking time may be less than or equal to approximately 6 hours.

Returning to FIG. 4, after the first organic film is formed on the first substrate, at least one inorganic film is formed on the first organic film (S402). FIG. 1 illustrates a cross-sectional view of a corresponding structure.

As shown in FIG. 1, the inorganic film 23 may be formed on the first organic film 21. The inorganic film 23 may be formed though, for example, plasma-enhanced chemical vapor deposition (PECVD), physical vapor deposition (PVD), atomic layer deposition (ALD), sol-gel process, etc. In one embodiment, as shown in FIG. 1, one inorganic film 23 may be formed on the first organic film 21.

Returning to FIG. 4, after the inorganic film is formed on the first organic film, a second organic film is formed on the first substrate disposed with the inorganic film (S403). FIG. 1 illustrates a cross-sectional view of a corresponding structure.

As shown in FIG. 1, the second organic film 22 may be formed on the inorganic film 23. In particular, a first film may be coated on the first substrate disposed with the inorganic film, then baked to obtain the second organic film. The baking temperature may be higher than or equal to approximately 400° C., and the baking time may be less than or equal to approximately 6 hours. The first organic film 21, the inorganic film 23, and the second organic film 22 may comprise the composite substrate 2.

Returning to FIG. 4, after the second organic film is formed on the first substrate disposed with the inorganic film, a display component is formed on the second organic film (S404). FIG. 1 illustrates a cross-sectional view of a corresponding structure.

As shown in FIG. 1, the display component including a driving element 3 and a displaying element 4 may be disposed on the second organic film 22. The driving element 3 may drive the displaying element 4 to display images and/or videos.

Returning to FIG. 4, after the display component is formed on the second organic film, the composite substrate is detached from the first substrate (S405). FIG. 1 illustrates a cross-sectional view of a corresponding structure. As shown in FIG. 1, the first substrate and the composite substrate 2 may be separated or detached from each other through, for example, laser cutting.

In the disclosed embodiments, before the composite substrate is detached from the first substrate (S405), an encapsulation layer may be formed on the display component and a protective layer may be attached to the encapsulation layer. FIG. 1 illustrates a cross-sectional view of a corresponding structure.

As shown in FIG. 1, the encapsulation layer 5 may be formed on the displaying element 4, and the protective layer 6 may be formed on the encapsulation layer 5. The encapsulation layer 5 may be a thin film encapsulation (TFE), which may seal the display component and prevent moisture and oxygen from penetrating the display component, otherwise the moisture and oxygen penetrating the display component may degrade the image performance of the display component. The protective layer 6 may protect the encapsulation layer 5.

In another embodiment, before forming the second organic film on the first substrate disposed with the inorganic film (S403), at least one third organic film may be formed on the inorganic film. The corresponding structure of the third organic film may be referred to FIG. 2.

As shown in FIG. 2, the third organic film 24 and the inorganic film 23 may be alternately arranged, and sandwiched between the first organic film 21 and the second organic film 22. Alternating arranged the third organic film 24 and the inorganic film 23 in the composite substrate 2 may provide desired moisture and oxygen barrier properties in the composite substrate 2 and, meanwhile, minimize the stress of the composite substrate 2. Accordingly, the display component including the driving element 3 and the displaying element 4 may be less affected by the moisture, oxygen, stress, etc.

In the disclosed embodiments, referring to FIG. 1, after the composite substrate 2 is detached from the first substrate 1, the lower protective layer may be no longer attached to a surface of the composite substrate away from the display component, because the composite substrate 2 itself may be able to efficiently prevent moisture and oxygen from penetrating the display component. Thus, the technical issues of attaching the lower protective layer to the composite substrate 2, such as bubbles, damages to the TFTs and organic light-emitting elements, may be solved, and the production yield of the flexible display devices may be improved accordingly.

Further, because the release layer may be no longer formed between the first substrate 1 and the composite substrate 2, the non-uniformity of the PI layer (i.e., the non-uniformity of the first organic film in the composite substrate) caused by the non-uniformity of the release layer and/or the glass substrate may be avoided. Accordingly, the production yield of the flexible display devices may be improved, and the image performance of the flexible display devices may be enhanced.

The description of the disclosed embodiments is provided to illustrate the present invention to those skilled in the art. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A flexible display device, comprising:
a composite substrate including a first organic film, a second organic film and at least one inorganic film sandwiched between the first organic film and the second organic film; and
a display component disposed on the composite substrate,
wherein the display component is disposed on the second organic film, and
the composite substrate is configured to support the display component and encapsulate the display component.

2. The flexible display device according to claim 1, wherein the composite substrate further includes:
at least one third organic film sandwiched between the first organic film and the second organic film, wherein the at least one inorganic film and the at least one third organic film are alternately arranged between the first organic film and the second organic film.

3. The flexible display device according to claim 2, wherein:
the first organic film, the second organic film, and the third organic film are made of polyimide.

4. The flexible display device according to claim 2, wherein:
the first organic film, the second organic film, and the third organic film have a thickness of approximately 10 μm-20 μm, respectively.

5. The flexible display device according to claim 1, wherein:
the inorganic film is made of at least one of silicon oxide, silicon nitride, aluminum, titanium, molybdenum, and aluminum oxide.

6. The flexible display device according to claim 1, wherein:
the inorganic film has a thickness of approximately 50 nm-500 nm.

7. The flexible display device according to claim 1, wherein:
the composite substrate has a thickness of approximately less than or equal to 50 μm.

8. A flexible display device fabrication method, comprising:
providing a first substrate;
forming a composite substrate on the first substrate;
forming a display component on the composite substrate; and
detaching the composite substrate from the first substrate,
wherein forming a composite substrate further includes forming a first organic film on the first substrate, forming at least one inorganic film on the first organic film, and forming a second organic film on the first substrate having the inorganic film,
the display component is formed on the second organic film, and
the composite substrate is configured to support the display component and encapsulate the display component.

9. The flexible display device fabrication method according to claim 8, wherein forming a first organic film on the first substrate further includes:
coating a first film on the first substrate; and
barking the first film to obtain the first organic film,
wherein a baking temperature is higher than or equal to approximately 400° C., and baking time is less than or equal to approximately 6 hours.

10. The flexible display device fabrication method according to claim 8, wherein:
the at least one inorganic film is formed by any one of plasma-enhanced chemical vapor deposition (PECVD), physical vapor deposition (PVD), atomic layer deposition (ALD), and sol-gel process.

11. The flexible display device fabrication method according to claim 8, wherein forming a second organic film on the first substrate having the inorganic film further includes:
coating a first film on the first substrate having the inorganic film; and
barking the first film to obtain the second organic film,
wherein a baking temperature is higher than or equal to approximately 400° C., and baking time is less than or equal to approximately 6 hours.

12. The flexible display device fabrication method according to claim 8, wherein detaching the composite substrate from the first substrate further includes:
irradiating laser on the composite substrate and the first substrate.

13. The flexible display device fabrication method according to claim 8, wherein forming a composite substrate further includes:
before forming the second organic film on the first substrate having the inorganic film, forming at least one third organic film on the first substrate having the inorganic film, wherein the at least one inorganic film and the at least one third organic film are alternately arranged between the first organic film and the second organic film.

14. The flexible display device fabrication method according to claim 13, wherein:
the first organic film, the second organic film, and the third organic film are made of polyimide.

15. The flexible display device fabrication method according to claim 13, wherein:
the first organic film, the second organic film, and the third organic film have a thickness of approximately 10 μm-20 μm, respectively.

16. The flexible display device fabrication method according to claim 8, wherein:
the first substrate is a glass substrate, or other rigid substrates.

17. The flexible display device fabrication method according to claim 8, wherein:
the inorganic film is made of at least one of silicon oxide, silicon nitride, aluminum, titanium, molybdenum, and aluminum oxide.

18. The flexible display device fabrication method according to claim 8, wherein:
the inorganic film has a thickness of approximately 50 nm-500 nm.

19. The flexible display device fabrication method according to claim 8, wherein:
the composite substrate has a thickness of approximately less than or equal to 50 μm.
